(19) United States
(12) Patent Application Publication
(10) Pub. No.: US 2012/0018209 A1
(43) Pub. Date: Jan. 26, 2012

(54) PRINTED CIRCUIT BOARD

(75) Inventor: Chang-Te Liao, Tu-Cheng (TW)

(73) Assignee: HON HAI PRECISION INDUSTRY CO., LTD., Tu-Cheng (TW)

(21) Appl. No.: 12/862,764

(22) Filed: Aug. 25, 2010

(30) Foreign Application Priority Data
Jul. 21, 2010 (CN) 201020265649.3

(51) Int. Cl. H05K 1/11

(52) U.S. Cl. 174/266

(57) ABSTRACT

A printed circuit board defines a groove used to engage with an electronic element. The groove defines a plurality of side walls. The PCB further defines a plurality of via holes at junctions between each two neighboring side walls. The via holes are communicate with the groove and have a C-shaped section. When the electronic element is received in the groove, the electronic element snugly engages with the plurality of side walls of the groove.

### BACKGROUND

1. Technical Field

The present disclosure generally relates to printed circuit boards (PCBs), and more particularly to a PCB defining a groove to receive an electronic element.

2. Description of Related Art

Referring to FIGS. 1-2, a PCB 10 is required to define a groove 12 having a plurality of sidewalls 121 to receive an electronic element 20. Generally, the groove 12 defines a plurality of corners 122, which are rounded, at the junctions between the sidewalls 121. When the electronic element 20 is received in the groove 12, the electronic elements 20 cannot snugly engage with the groove 12, leading the electronic element 20 to be loose in the groove 12 (as shown in FIG. 1) or interfere with the groove 12 (as shown in FIG. 2).

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is one assembled view of a PCB received with an electronic element in prior art.

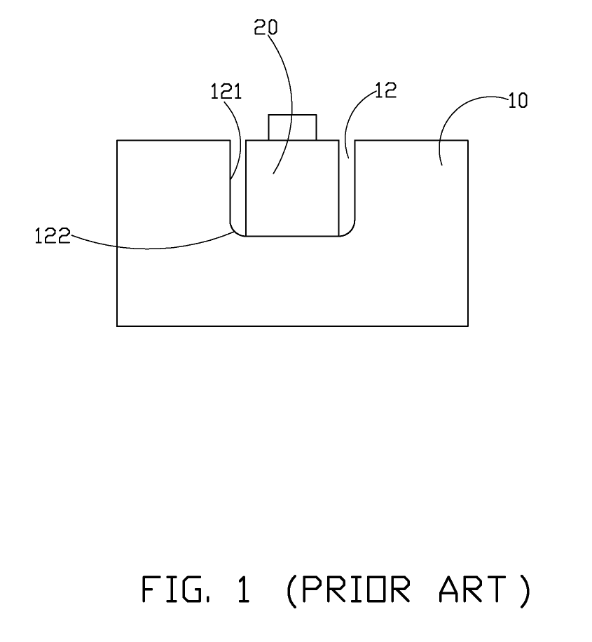

FIG. 2 is another assembled view of a PCB received with an electronic element in prior art.

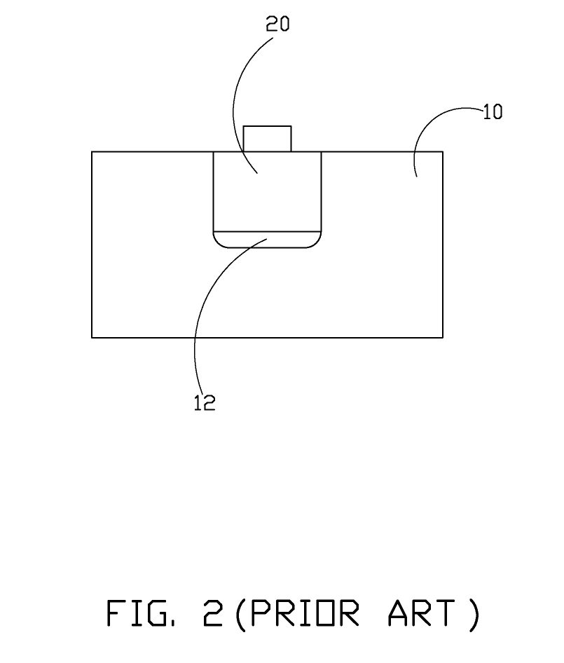

FIG. 3 is an exploded view of one embodiment of a PCB received with an electronic element in accordance with the present invention.

FIG. 4 is an assembled view of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

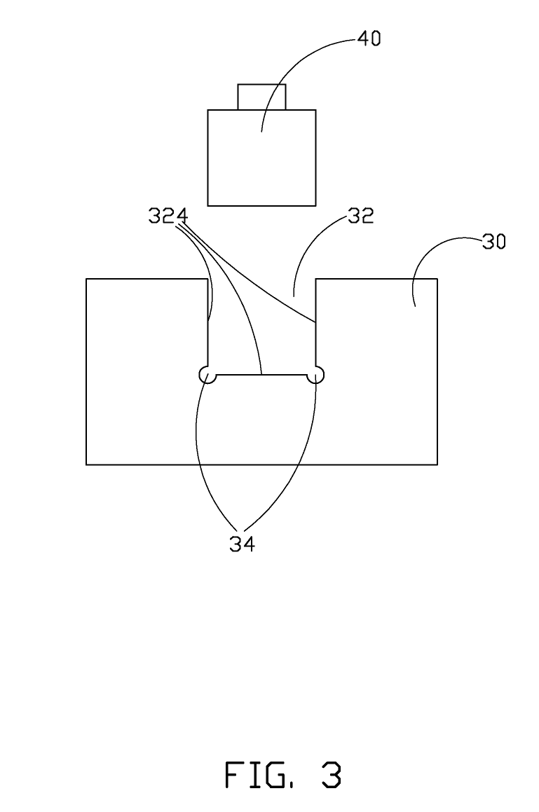

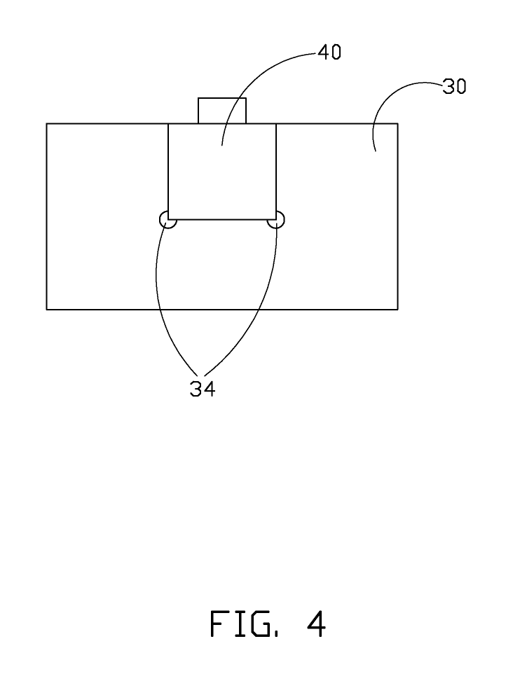

Referring to FIGS. 3-4, a PCB 30 defines at least one groove 32 to receive a corresponding electronic element 40. The groove 32 is defined by a plurality of side walls 324. The PCB 30 further defines a plurality of via holes 34 at junctions of each two neighboring side walls 324. The via holes 34 communicate with the groove 32 and have a substantial C-shaped section. In this embodiment, the groove 32 defines three side walls 324 substantially perpendicular to each other, and the PCB 30 defines two via holes 34. That is, the groove 32 is rectangularly-shaped, accordingly, the electronic element 40 comprises a rectangle portion engaging with the groove 32 snugly.

When the electronic element 40 is received in the groove 32, the electronic element 40 engages with the plurality of side walls 324 of the groove 32 snugly due to the via holes 34 making concave corners at junctions between each two neighboring side walls. Therefore, the electronic element 40 is received in the groove 32 without looseness and interference.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A printed circuit board, defining at least one groove to receive a corresponding electronic element, the groove being defined by a plurality of side walls, the PCB further defining a plurality of via holes at junctions of each two neighboring side walls, the via holes in communication with the groove and having a substantial C-shaped section.

2. The printed circuit board as claimed in claim 1, wherein the plurality of side walls are substantially perpendicular to each other.
